(19) United States
(12) Patent Application Publication
(10) Pub. No.: US 2012/0205811 A1
(43) Pub. Date: Aug. 16, 2012

(54) INTEGRATED CIRCUIT PACKAGING SYSTEM WITH TERMINAL LOCKS AND METHOD OF MANUFACTURE THEREOF

(76) Inventors: Byung Tai Do, Singapore (SG); Linda Pei Ee Chua, Singapore (SG); Arnel Senosa Trasporto, Singapore (SG)

(21) Appl. No.: 13/366,768

(22) Filed: Feb. 6, 2012

Related U.S. Application Data
(60) Provisional application No. 61/442,797, filed on Feb. 14, 2011.

(51) Int. Cl. H01L 23/48; H01L 21/56

(52) U.S. Cl. 257/773; 438/127; 257/E21.502; 257/E23.01

(57) ABSTRACT

A method of manufacture of an integrated circuit packaging system includes: providing a terminal having a cornered dimple formed therein as a simple concave polygon; mounting an integrated circuit above and coupled to the terminal; and forming an encapsulation encapsulating the integrated circuit and portions of the terminal.

### CROSS-REFERENCE TO RELATED APPLICATION

This application claims the benefit of U.S. Provisional Patent Application Ser. No. 61/442,797 filed Feb. 14, 2011, and the subject matter thereof is incorporated herein by reference thereto.

### TECHNICAL FIELD

The present invention relates generally to an integrated circuit packaging system and more particularly to a system for utilizing a terminal in an integrated circuit packaging system.

### BACKGROUND

The rapidly growing market for portable electronic devices, e.g. cellular phones, laptop computers, and personal digital assistants (PDAs), is an integral facet of modern life. The multitude of portable devices represents one of the largest potential market opportunities for next generation packaging. These devices have unique attributes that have significant impacts on manufacturing integration, in that they must be generally small, lightweight, and rich in functionality and they must be produced in high volumes at relatively low cost.

As an extension of the semiconductor industry, the electronics packaging industry has witnessed ever-increasing commercial competitive pressures, along with growing consumer expectations and the diminishing opportunities for meaningful product differentiation in the marketplace.

Packaging, materials engineering, and development are at the very core of these next generation electronics insertion strategies outlined in road maps for development of next generation products. Future electronic systems can be more intelligent, have higher density, use less power, operate at higher speed, and can include mixed technology devices and assembly structures at lower cost than today.

There have been many approaches to addressing the advanced packaging requirements of microprocessors and portable electronics with successive generations of semiconductors. Many industry road maps have identified significant gaps between the current semiconductor capability and the available supporting electronic packaging technologies. The limitations and issues with current technologies include increasing clock rates, EMI radiation, thermal loads, second level assembly reliability stresses and cost.

As these package systems evolve to incorporate more components with varied environmental needs, the pressure to push the technological envelope becomes increasingly challenging. More significantly, with the ever-increasing complexity, the potential risk of error increases greatly during manufacture.

In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Thus, a need remains for smaller footprints and more robust packages and methods for manufacture. Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing a terminal having a cornered dimple formed therein as a simple concave polygon; mounting an integrated circuit above and coupled to the terminal; and forming an encapsulation encapsulating the integrated circuit and portions of the terminal.

The present invention provides an integrated circuit packaging system, including: a terminal with a terminal cornered dimple formed therein as a simple concave polygon; an integrated circuit mounted above and coupled to the terminal; and an encapsulation encapsulating the integrated circuit and portions of the terminal.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit packaging system along the line 1-1 of FIG. 2 in a first embodiment of the present invention.

FIG. 2 is a top view of the integrated circuit packaging system of FIG. 1.

FIG. 3 is a detailed view of the region 3-3 of the integrated circuit packaging system FIG. 1.

FIG. 4 is a cross-sectional view of the integrated circuit packaging system of FIG. 1 after a tape attachment phase of manufacture.

FIG. 5 is a cross-sectional view of the integrated circuit packaging system of FIG. 4 after a die attachment phase of manufacture.

FIG. 6 is a cross-sectional view of the integrated circuit packaging system of FIG. 5 after a wire bonding phase of manufacture.

FIG. 7 is a cross-sectional view of the integrated circuit packaging system of FIG. 6 after an encapsulation phase of manufacture.

FIG. 8 is a cross-sectional view of the integrated circuit packaging system of FIG. 7 after a singulation phase of manufacture.

FIG. 9 is a detailed bottom view of an integrated circuit packaging system after a dimple forming phase of manufacture in a second embodiment of the present invention.

FIG. 10 is a cross-sectional view of the integrated circuit packaging system of FIG. 9 along the line 10-10.

FIG. 11 is a cross-sectional view of the integrated circuit packaging system of FIG. 9 along the line 11-11.

FIG. 12 is a cross-sectional view of an integrated circuit packaging system along the line 12-12 of FIG. 13 in a third embodiment of the present invention.

FIG. 13 is a detailed bottom view of the region 13-13 of the integrated circuit packaging system FIG. 12.

FIG. 14 is a detailed bottom view of an integrated circuit packaging system in a fourth embodiment of the present invention.

FIG. 15 is a flow chart of a method of manufacture of the integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes can be made without departing from the scope of the present invention.

In the following description, numerous specific details are given to provide a thorough understanding of the invention. However, it will be apparent that the invention can be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

In addition, where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane of a top surface of the die pad, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements without having any intervening material.

The term “processing” as used herein includes deposition of material or photoresist, patterning, exposure, development, etching, cleaning, and/or removal of the material or photoresist as required in forming a described structure.

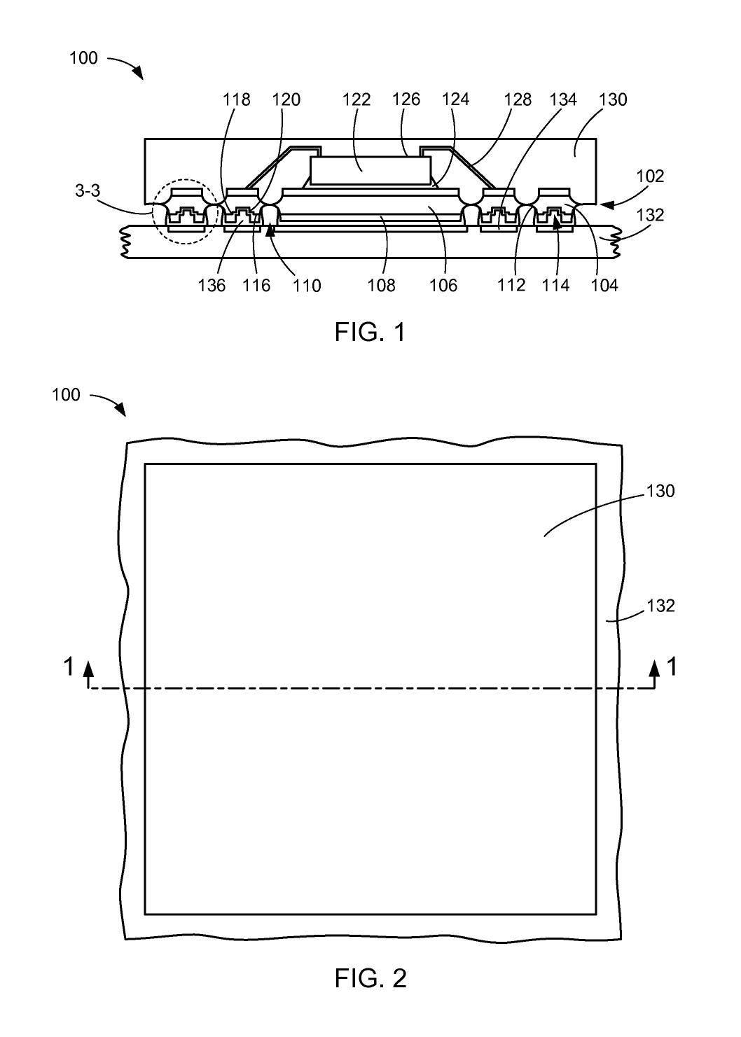

Referring now to FIG. 1, therein is shown a cross-sectional view of an integrated circuit packaging system 100 along the line 1-1 of FIG. 2 in a first embodiment of the present invention. The integrated circuit packaging system 100 is shown having a leadframe artifact 102. The leadframe artifact 102 can have terminals 104 and a die pad 106. The leadframe artifact 102 is defined as a conductive structure provided to support components thereon during manufacture and being incorporated into the final product.

The die pad 106 can be centered in the leadframe artifact 102 and surrounded by the terminals 104. The terminals 104 can be arranged in two rows surrounding the die pad 106. The leadframe artifact 102 can have a plating layer 108 covering a top and bottom of the die pad 106 and the terminals 104. The die pad 106 and the terminals 104 have separation grooves 110 therebetween to separate the die pad 106 from the terminals 104 and the terminals 104 from one another.

The separation grooves 110 can create standoff portions 112 on the terminals 104 and the die pad 106. The standoff portions 112 allow for increased density of the terminals 104 within the leadframe artifact 102 since the terminals 104 can traverse a greater vertical space over a smaller horizontal space.

The terminals 104 can have cornered dimples 114 formed into a bottom surface 116 of the terminals 104. The bottom surface 116 can be flat or planar peripheral to the cornered dimples 114 on portions where the cornered dimples 114 are not formed.

The cornered dimples 114 have lower steps 118 and upper steps 120 formed as the corners of the cornered dimples 114. The cornered dimples 114 can be formed by etching, laser ablation, or mechanical drill. The dimensions of the cornered dimples 114 can be 100 μm-200 μm in width and 0.03 mm-0.06 mm in depth at angles of about 90° and be formed entirely of horizontal and vertical flat surfaces. The cornered dimples 114 can be simple concave polygon from a side view defined as having at least one of its internal angles greater than 180°.

The cornered dimples 114 can be symmetrical having the upper steps 120 and the lower steps 118 symmetrically placed within the bottom surface 116 of the terminals 104. The upper steps 120 can be formed in closer proximity facing one another than the lower steps 118.

The plating layer 108 can be formed on the bottom surface 116 of the terminals 104 and plates the cornered dimples 114 along the upper steps 120 and the lower steps 118. The plating layer 108 can be formed to follow the upper steps 120 without wholly filling the cornered dimples 114 created by the upper steps 120 and the lower steps 118. The plating layer 108 can also be formed only on the bottom surface 116 of the terminals 104 and not extending onto or plating the standoff portions 112, although the standoff portions 112 can optionally be coated by the plating layer 108.

The leadframe artifact 102 can be used to support an integrated circuit 122. The integrated circuit 122 can be attached to the die pad 106 of the leadframe artifact 102 with a die attach adhesive 124. The integrated circuit 122 can have an active side 126 facing away from the leadframe artifact 102. The active side 126 is defined as a surface having active circuitry fabricated thereon.

The active side 126 can be electrically connected to the terminals 104 of the leadframe artifact 102 with interconnects 128. The interconnects 128, the integrated circuit 122, and portions of the terminals 104 and the die pad 106 can be encapsulated with an encapsulation 130. The encapsulation 130 is defined as a structure that provides a hermetic seal and protects sensitive components from moisture, dust and other contamination. The encapsulation 130 can be glob top, film assist molding, or other encasement structures.

The leadframe artifact 102 can be mounted to a board 132 having the die pad 106 and the terminals 104 aligned with contacts 134 within the board 132. The die pad 106 and the terminals 104 are attached to the board 132 with a conductor 136 such as a paste or a solder ball. The paste can be a conductive paste to conduct electric signals or exhaust heat.

It has been discovered that the cornered dimples 114 formed as simple concave polygons unexpectedly provide enhanced locking ability between the terminals 104 and the conductor 136 since the lower steps 118 and the upper steps 120 provide greater surface area and optimal angles for the conductor 136 to adhere to as the conductor 136 fills into the cornered dimples 114.

It has also been discovered that the cornered dimples 114 unexpectedly enhance the conductor 136 coverage of the terminals 104 improving reliability of the joint between the terminals 104 and the contacts 134 of the board 132.

Referring now to FIG. 2, therein is shown a top view of the integrated circuit packaging system 100 of FIG. 1. The integrated circuit packaging system 100 is shown having the encapsulation 130 above the leadframe artifact 102 of FIG. 1 and above the board 132. The leadframe artifact 102 of FIG. 1 can be arranged on the board 132 having greatly enhanced density of connections between the board 132 and the terminals 104 of FIG. 1 since the surface area of the cornered dimples 114 of FIG. 1 is greatly increased the terminals 104 of FIG. 1 can be smaller allowing for smaller overall dimensions or greater number of channels in the same area. The board 132 can have more useable area for other components or be shrunk entirely to fit ever decreasing device layouts.

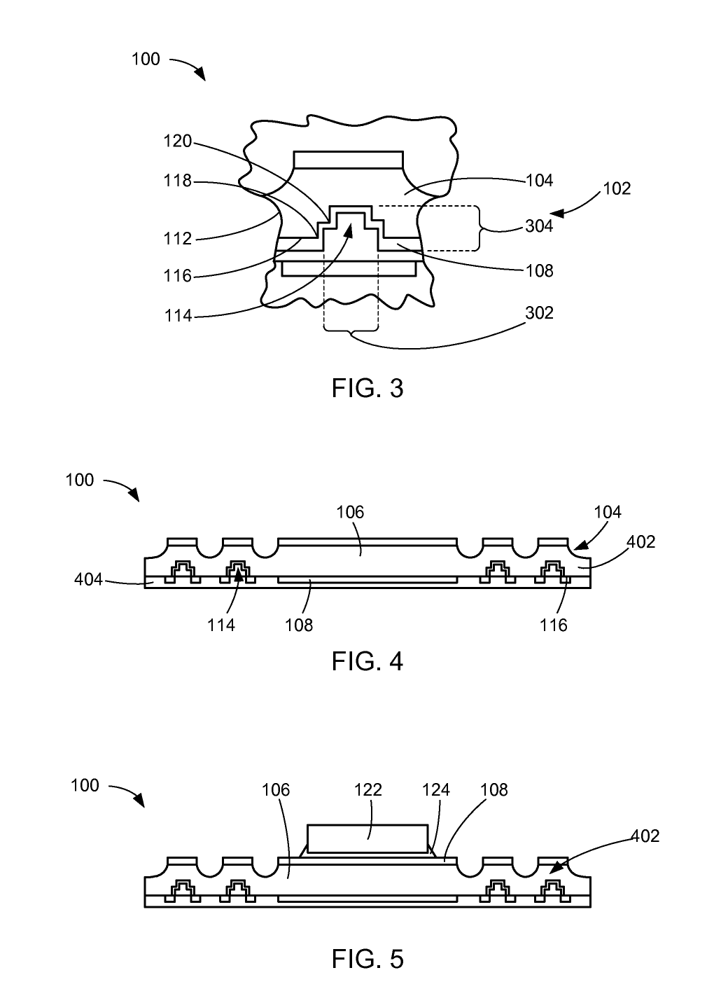

Referring now to FIG. 3, therein is shown a detailed view of the region 3-3 of the integrated circuit packaging system 100 FIG. 1. The integrated circuit packaging system 100 is shown having one of the terminals 104 of the leadframe artifact 102 of FIG. 1.

The terminals 104 can have the cornered dimples 114 formed into the bottom surface 116 of the terminals 104. The bottom surface 116 can be flat or planar peripheral to the cornered dimples 114 on portions where the cornered dimples 114 are not formed.

The cornered dimples 114 have the lower steps 118 and the upper steps 120 formed as the corners of the cornered dimples 114. The cornered dimples 114 can be formed by etching, laser ablation, or mechanical drill. The dimensions of the cornered dimples 114 can be 100 μm-200 μm along a width 302 and 0.03 mm-0.06 mm along a depth 304.

The cornered dimples 114 can be symmetrical having the upper steps 120 and the lower steps 118 symmetrically placed within the bottom surface 116 of the terminals 104. The upper steps 120 can be formed in closer proximity facing one another than the lower steps 118.

The plating layer 108 can be formed on the bottom surface 116 of the terminals 104 and plates the cornered dimples 114 along the upper steps 120 and the lower steps 118. The plating layer 108 can be formed to follow the upper steps 120 and the lower steps 118 without wholly filling the cornered dimples 114 created by the upper steps 120 and the lower steps 118. The plating layer 108 can also be formed only on the bottom surface 116 of the terminals 104 and not extending onto or plating the standoff portions 112, although the standoff portions 112 can optionally be coated by the plating layer 108.

Referring now to FIG. 4, therein is shown a cross-sectional view of the integrated circuit packaging system 100 of FIG. 1 after a tape attachment phase of manufacture. The integrated circuit packaging system 100 is shown having a leadframe 402 with the cornered dimples 114 formed on the bottom surface 116 of the terminals 104. A tape 404 can be attached to the leadframe 402 and covering the plating layer 108.

The tape 404 can support or make the leadframe 402 easier to handle and manipulate during processing. Optionally the tape 404 can be disregarded and the leadframe 402 processed without the tape 404.

The cornered dimples 114 have been formed in the leadframe 402 and the plating layer 108 has been formed on the leadframe 402. The separation grooves 110 of FIG. 1 have not been formed into the leadframe 402 to create the standoff portions 112 of FIG. 1 or to separate the terminals 104 from one another and the terminals 104 from the die pad 106.

Referring now to FIG. 5, therein is shown a cross-sectional view of the integrated circuit packaging system 100 of FIG. 4 after a die attachment phase of manufacture. The integrated circuit packaging system 100 is shown having the integrated circuit 122 attached to the die pad 106 with the die attach adhesive 124. The integrated circuit 122 can be horizontally smaller than the die pad 106.

The die pad 106 can extend horizontally beyond the integrated circuit 122. The die attach adhesive 124 can be in direct contact with the integrated circuit 122 and the plating layer 108 of the leadframe 402 covering the die pad 106.

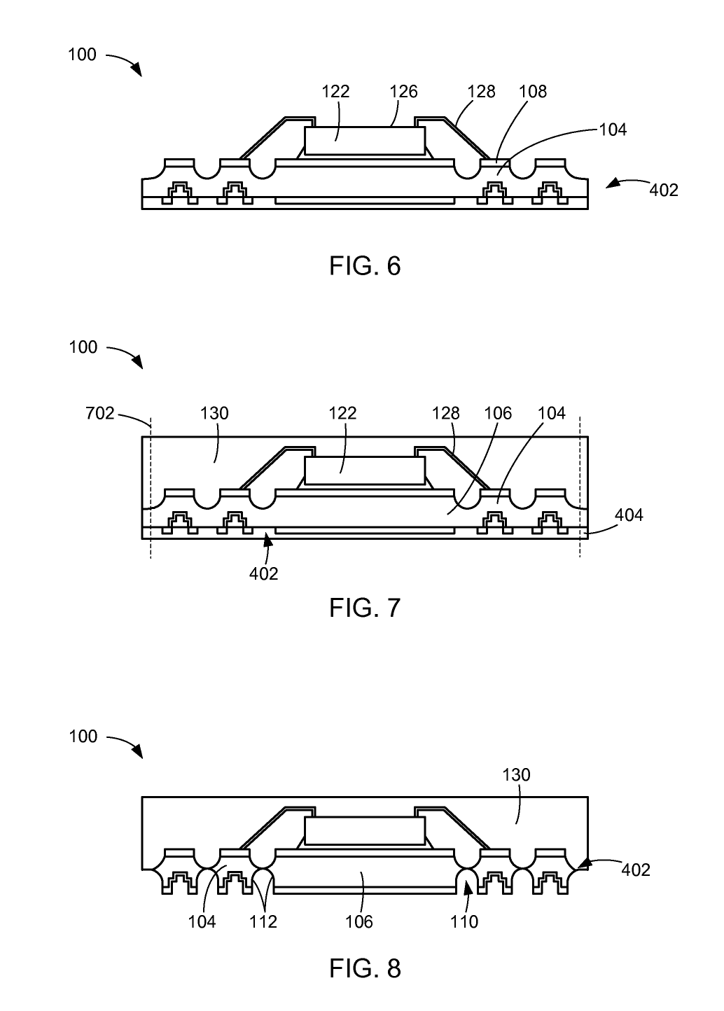

Referring now to FIG. 6, therein is shown a cross-sectional view of the integrated circuit packaging system 100 of FIG. 5 after a wire bonding phase of manufacture. The integrated circuit packaging system 100 is shown having the interconnects 128 connecting between the active side 126 of the integrated circuit 122 and the plating layer 108 of the leadframe 402 covering the terminals 104.

Referring now to FIG. 7, therein is shown a cross-sectional view of the integrated circuit packaging system 100 of FIG. 6 after an encapsulation phase of manufacture. The integrated circuit packaging system 100 is shown having the integrated circuit 122, the interconnects 128, the terminals 104 and the die pad 106 encapsulated by the encapsulation 130. The encapsulation 130 and the leadframe 402 can have singulation lines 702 vertically traversing from the tape 404 through the leadframe 402 and through the encapsulation 130.

Referring now to FIG. 8, therein is shown a cross-sectional view of the integrated circuit packaging system 100 of FIG. 7 after a singulation phase of manufacture. The integrated circuit packaging system 100 is shown having the leadframe 402 and the encapsulation 130 singulated along the singulation lines 702 of FIG. 7. The tape 404 of FIG. 4 has been removed and the separation grooves 110 have been formed in the leadframe 402 to separate the terminals 104 from one another and to separate the terminals 104 from the die pad 106. The separation grooves 110 have also been formed to create the standoff portions 112 on the terminals 104 and the die pad 106.

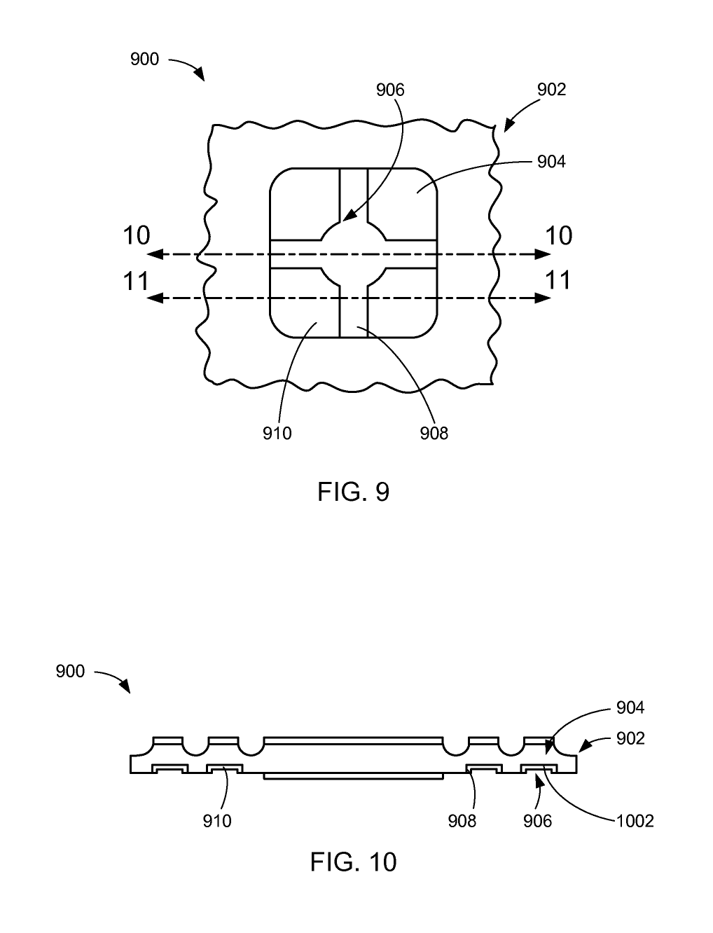

Referring now to FIG. 9, therein is shown a detailed bottom view of an integrated circuit packaging system 900 after a dimple forming phase of manufacture in a second embodiment of the present invention. The integrated circuit packaging system 900 is shown having a leadframe 902 with terminals 904. The integrated circuit packaging system 900 can be similar to the integrated circuit packaging system 100 of FIG. 1 and FIG. 9 depicts the portion 3-3 of FIG. 1 for this embodiment.

The leadframe 902 is defined as a conductive structure provided to support components thereon during manufacture and incorporated into the final product. The terminals 904 can have cornered dimples 906 formed into the terminals 904. The cornered dimples 906 can have a geometric pattern 908 formed as the corners of the cornered dimples 906. The cornered dimples 906 can be formed by etching, laser ablation, or mechanical drill at angles of about 90° and be formed entirely of horizontal and vertical flat surfaces. The cornered dimples 906 can be a simple concave polygon from a bottom view defined as having at least one of its internal angles greater than 180°.

The cornered dimples 906 can be symmetrical having the geometric pattern 908 symmetrically placed within the terminals 904. A plating layer 910 can be formed on the terminals 904 and plates the cornered dimples 906 along the geometric pattern 908. The plating layer 910 can be formed to follow the geometric pattern 908 without wholly filling the cornered dimples 906 created by the geometric pattern 908.

It has been discovered that the cornered dimples 906 formed as simple concave polygons unexpectedly provide enhanced locking ability between the terminals 904 and a conductor (not shown) since the geometric pattern 908 provide greater surface area and optimal angles for conductor to adhere to as conductor can fill into the cornered dimples 906. It has also been discovered that the cornered dimples 906 unexpectedly enhance conductor coverage of the terminals 904 improving reliability of the joint between the terminals 904 and an external board (not shown).

Referring now to FIG. 10, therein is shown a cross-sectional view of the integrated circuit packaging system 900 of FIG. 9 along the line 10-10. The integrated circuit packaging system 900 is shown having the terminals 904 with the cornered dimples 906 formed on a bottom surface 1002 of the terminals 904. The geometric pattern 908 is shown traversing an entire width of the bottom surface 1002 of the terminals 904.

The bottom surface 1002 of the terminals 904 is shown having the plating layer 910 formed thereon. The leadframe 902 can also have a die pad 1004. The plating layer 910 can coat a top and bottom of the die pad 1004. The plating layer 910 can be formed to follow the geometric pattern 908 without wholly filling the cornered dimples 906 created by the geometric pattern 908.

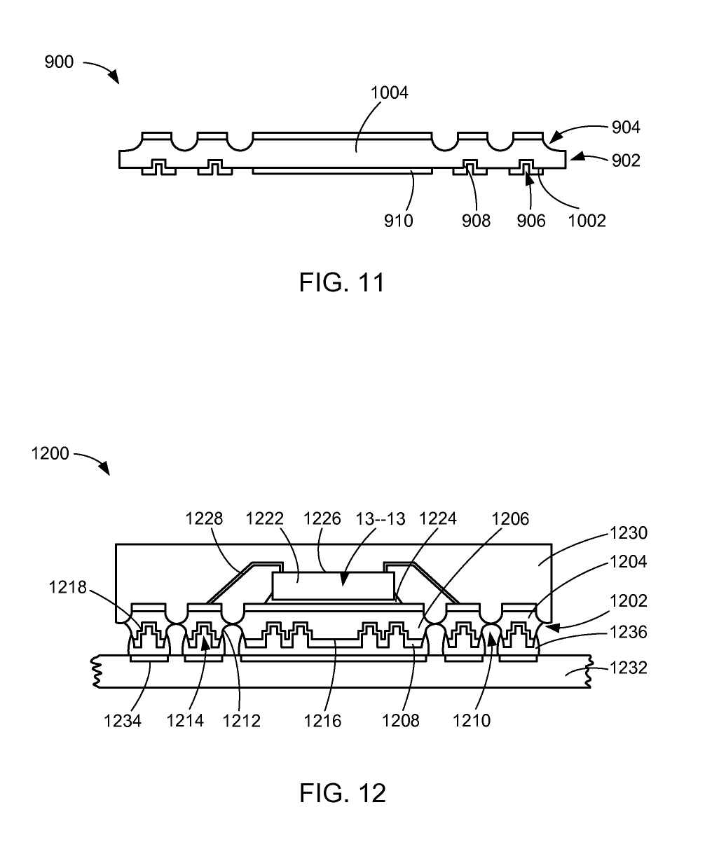

Referring now to FIG. 11, therein is shown a cross-sectional view of the integrated circuit packaging system 900 of FIG. 9 along the line 11-11. The integrated circuit packaging system 900 is shown having the terminals 904 with the cornered dimples 906 formed on the bottom surface 1002 of the terminals 904. The geometric pattern 908 is shown traversing only a portion of a width of the bottom surface 1002 of the terminals 904.

The bottom surface 1002 of the terminals 904 is shown having the plating layer 910 formed thereon. The leadframe 902 can also have the die pad 1004. The plating layer 910 can coat a top and bottom of the die pad 1004. The plating layer 910 can be formed to follow the geometric pattern 908 without wholly filling the cornered dimples 906 created by the geometric pattern 908.

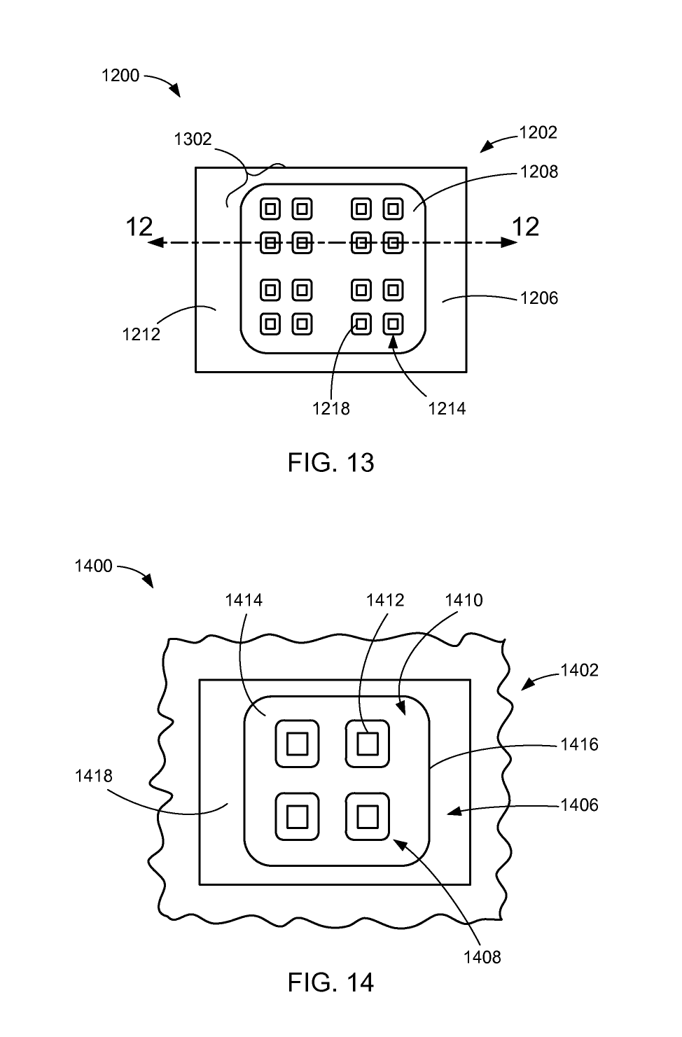

Referring now to FIG. 12, therein is shown a cross-sectional view of an integrated circuit packaging system 1200 along the line 12-12 of FIG. 13 in a third embodiment of the present invention. The integrated circuit packaging system 1200 is shown having a leadframe artifact 1202. The leadframe artifact 1202 can have terminals 1204 and a die pad 1206. The leadframe artifact 1202 is defined as a conductive structure provided to support components thereon during manufacture and being incorporated into the final product.

The die pad 1206 can be centered in the leadframe artifact 1202 and surrounded by the terminals 1204. The terminals 1204 can be arranged in two rows surrounding the die pad 1206. The leadframe artifact 1202 can have a plating layer 1208 covering a top and bottom of the die pad 1206 and the terminals 1204. The die pad 1206 and the terminals 1204 have separation grooves 1210 therebetween to separate the die pad 1206 from the terminals 1204 and the terminals 1204 from one another.

The separation grooves 1210 can create standoff portions 1212 on the terminals 1204 and the die pad 1206. The standoff portions 1212 allow for increased density of the terminals 1204 within the leadframe artifact 1202 since the terminals 1204 can traverse a greater vertical space over a smaller horizontal space.

The terminals 1204 and the die pad 1206 can have cornered dimples 1214 formed into a bottom surface 1216. The bottom surface 1216 can be flat or planar peripheral to the cornered dimples 1214 on portions where the cornered dimples 1214 are not formed.

The cornered dimples 1214 have steps 1218 formed as the corners of the cornered dimples 1214. The cornered dimples 1214 can be formed by etching, laser ablation, or mechanical drill. The dimensions of the cornered dimples 1214 can be 100 μm-200 μm in width and 0.03 mm-0.06 mm in depth at angles of about 90° and be formed entirely of horizontal and vertical flat surfaces. The cornered dimples 1214 can be simple concave polygon from a side view defined as having at least one of its internal angles greater than 180°.

The cornered dimples 1214 can be symmetrical having the steps 1218 symmetrically placed within the bottom surface 1216 of the terminals 1204 and the die pad 1206. The plating layer 1208 can be formed on the bottom surface 1216 and plates the cornered dimples 1214 along the steps 1218. The plating layer 1208 can be formed to follow the steps 1218 without wholly filling the cornered dimples 1214 created by the steps 1218. The plating layer 1208 can also be formed only on the bottom surface 1216 of the terminals 1204 and the die pad 1206 and not extending onto or plating the standoff portions 1212, although the standoff portions 1212 can optionally be coated by the plating layer 1208.

The leadframe artifact 1202 can be used to support an integrated circuit 1222. The integrated circuit 1222 can be attached to the die pad 1206 of the leadframe artifact 1202 with a die attach adhesive 1224. The integrated circuit 1222 can have an active side 1226 facing away from the leadframe artifact 1202. The active side 1226 is defined as a surface having active circuitry fabricated thereon.

The active side 1226 can be electrically connected to the terminals 1204 of the leadframe artifact 1202 with interconnects 1228. The interconnects 1228, the integrated circuit 1222, and portions of the terminals 1204 and the die pad 1206 can be encapsulated with an encapsulation 1230. The encapsulation 1230 is defined as a structure that provides a hermetic seal and protects sensitive components from moisture, dust and other contamination. The encapsulation 1230 can be glob top, film assist molding, or other encasement structures.

The leadframe artifact 1202 can be mounted to a board 1232 having the die pad 1206 and the terminals 1204 aligned with contacts 1234 within the board 1232. The die pad 1206 and the terminals 1204 are attached to the board 1232 with a conductor 1236 such as a paste or a solder ball. The paste can be a conductive paste to conduct electric signals or exhaust heat.

It has been discovered that the cornered dimples 1214 formed as simple concave polygons unexpectedly provide enhanced locking ability between the conductor 1236 on the terminals 1204 and the die pad 1206 since the steps 1218 provide greater surface area and optimal angles for the conductor 1236 to adhere to as the conductor 1236 fills into the cornered dimples 1214. It has also been discovered that the cornered dimples 1214 unexpectedly enhance the conductor 1236 coverage of the terminals 1204 improving reliability of the joint between the terminals 1204 and the contacts 1234 of the board 1232.

Referring now to FIG. 13, therein is shown a detailed bottom view of the region 13-13 of the integrated circuit packaging system 1200 FIG. 12. The integrated circuit packaging system 1200 is shown having the leadframe artifact 1202 including the die pad 1206.

The die pad 1206 can have the cornered dimples 1214 arranged in clusters 1302 symmetrically positioned across the die pad 1206. The steps 1218 can be centered symmetrically within the cornered dimples 1214.

The plating layer 1208 can cover the cornered dimples 1214 and the bottom surface 1216 of the die pad 1206 but is not covering the standoff portions 1212 of the die pad 1206. The plating layer 1208 covering the bottom surface 1216 can be shown in a center of the die pad 1206 with the standoff portions 1212 surrounding the plating layer 1208.

Referring now to FIG. 14, therein is shown a detailed bottom view of an integrated circuit packaging system 1400 in a fourth embodiment of the present invention. The integrated circuit packaging system 1400 is shown having a leadframe artifact 1402 including a die pad 1406. The integrated circuit packaging system 1400 can be similar to the integrated circuit packaging system 1200 of FIG. 12 and FIG. 14 depicts the portion 13-13 of FIG. 12 for this embodiment.

The die pad 1406 can have cornered dimples 1408 arranged singularly and in corners 1410 of the die pad 1406. The cornered dimples 1408 can include steps 1412. The steps 1412 can be centered symmetrically within the cornered dimples 1408. The cornered dimples 1408 can be simple concave polygon from a side view defined as having at least one of its internal angles greater than 180°.

The die pad 1406 can be coated with a plating layer 1414 and can cover the cornered dimples 1408 and a bottom surface 1416 of the die pad 1406 but is not covering standoff portions 1418 of the die pad 1406. The plating layer 1414 covering the bottom surface 1416 can be shown in a center of the die pad 1406 with the standoff portions 1418 surrounding the plating layer 1414.

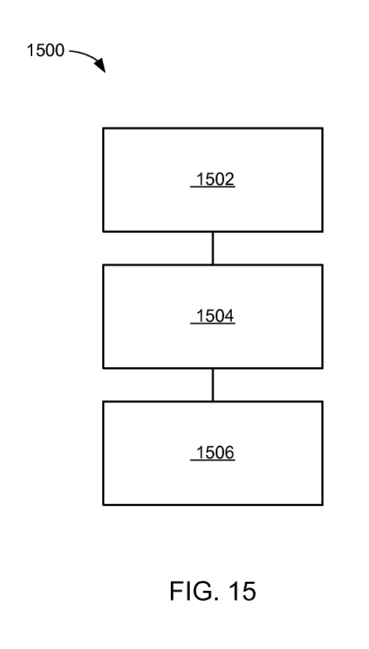

Referring now to FIG. 15, therein is shown a flow chart of a method 1500 of manufacture of the integrated circuit packaging system in a further embodiment of the present invention. The method 1500 includes: providing a terminal having a cornered dimple formed therein as a simple concave polygon in a block 1502; mounting an integrated circuit above and coupled to the terminal in a block 1504; and forming an encapsulation encapsulating the integrated circuit and portions of the terminal in a block 1506.

Thus, it has been discovered that the integrated circuit packaging system and cornered dimples of the present invention furnishes important and heretofore unknown and unavailable solutions, capabilities, and functional aspects for integrated circuit packaging system configurations. The resulting processes and configurations are straightforward, cost-effective, uncomplicated, highly versatile, accurate, sensitive, and effective, and can be implemented by adapting known components for ready, efficient, and economical manufacturing, application, and utilization.

Another important aspect of the present invention is that it valuably supports and services the historical trend of reducing costs, simplifying systems, and increasing performance. These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing a terminal having a cornered dimple formed therein as a simple concave polygon;
mounting an integrated circuit above and coupled to the terminal; and
forming an encapsulation encapsulating the integrated circuit and portions of the terminal.

2. The method as claimed in claim 1 further comprising filling a conductor into the terminal cornered dimple.

3. The method as claimed in claim 1 further comprising forming a plating layer lining the cornered dimple.

4. The method as claimed in claim 1 wherein providing the terminal includes providing the terminal having the cornered dimple formed as an upper step and a lower step.

5. The method as claimed in claim 1 wherein providing the terminal includes providing the terminal having a standoff portion formed thereon and encompassing the cornered dimple.

6. A method of manufacture of an integrated circuit packaging system comprising:
providing a leadframe having a terminal, a die pad and a cornered dimple formed as a simple concave polygon;
mounting an integrated circuit over and coupled to the die pad;
connecting an interconnect between the integrated circuit and the terminal;
forming an encapsulation encapsulating the integrated circuit and portions of the terminal and the die pad; and
forming separation grooves in the leadframe separating the terminals and the die pad.

7. The method as claimed in claim 6 wherein providing the leadframe includes providing the leadframe having the die pad having the cornered dimple formed therein.

8. The method as claimed in claim 6 wherein providing the leadframe includes providing the leadframe having the cornered dimple includes the cornered dimple formed as a geometric pattern.

9. The method as claimed in claim 6 wherein providing the leadframe includes providing the leadframe having the die pad with a standoff portion formed on the die pad.

10. The method as claimed in claim 6 further comprising forming a plating layer on a top and on a bottom of the leadframe.

11. An integrated circuit packaging system comprising:
a terminal with a terminal cornered dimple formed therein as a simple concave polygon;
an integrated circuit mounted above and coupled to the terminal; and
an encapsulation encapsulating the integrated circuit and portions of the terminal.

12. The system as claimed in claim 11 further comprising a conductor filling the terminal cornered dimple.

13. The system as claimed in claim 11 further comprising a plating layer lining the terminal cornered dimple.

14. The system as claimed in claim 11 wherein the terminal includes the terminal cornered dimple formed as an upper step and a lower step.

15. The system as claimed in claim 11 wherein the terminal includes a standoff portion formed on the terminal and encompassing the terminal cornered dimple.

16. The system as claimed in claim 11 further comprising:
a die pad coupled to the terminal and attached to the integrated circuit; and
an interconnect between the integrated circuit and the terminal.

17. The system as claimed in claim 16 wherein the die pad includes a die pad cornered dimple formed therein.

18. The system as claimed in claim 16 wherein the terminal includes the terminal cornered dimple formed as a geometric pattern.

19. The system as claimed in claim 16 wherein the die pad includes a standoff portion formed thereon.

20. The system as claimed in claim 16 further comprising a plating layer formed on a top and on a bottom of the terminal.
